(19) United States
(12) Patent Application Publication
(10) Pub. No.: US 2017/0062622 A1
(43) Pub. Date: Mar. 2, 2017

(54) THIN FILM TRANSISTOR ARRAY PANEL AND METHOD OF MANUFACTURING THE SAME

(71) Applicant: SAMSUNG DISPLAY CO., LTD., YONGIN-SI (KR)

(72) Inventors: HYE HYANG PARK, YONGIN-SI (KR); EUN HYUN KIM, SUWON-SI (KR); TAE YOUNG KIM, SEONGNAM-SI (KR); YEON KEON MOON, SEOUL (KR); SHIN HYUK YANG, SEONGNAM-SI (KR)

(21) Appl. No.: 15/235,201

(22) Filed: Aug. 12, 2016

(30) Foreign Application Priority Data
Sep. 2, 2015 (KR) 10-2015-0124329

(51) Int. Cl. H01L 29/786; H01L 29/49; H01L 27/12

(52) U.S. Cl. CPC H01L 29/78606; H01L 27/1222; H01L 29/4908; H01L 29/78678; H01L 29/78696; H01L 29/78618; H01L 27/1288

(57) ABSTRACT

A thin film transistor array panel according to an exemplary embodiment of the present invention includes a substrate and a gate electrode disposed on the substrate. A gate insulating layer is disposed on the substrate and covers the gate electrode. A semiconductor layer is disposed on the gate insulating layer and includes a channel region, a source region, and a drain region. The source and drain regions are separated from each other by the channel region. An etch stopper is disposed on the semiconductor layer. A passivation layer is disposed on the semiconductor layer and covers the etch stopper. A source electrode and a drain electrode are disposed on the passivation layer and are respectively connected to the source region and the drain region. The passivation layer includes a first sub-passivation layer including aluminum oxide (AlOₓ).

### CROSS-REFERENCE TO RELATED APPLICATION

This application claims priority under 35 U.S.C. §119 to Korean Patent Application No. 10-2015-0124329 filed in the Korean Intellectual Property Office on Sep. 02, 2015, the disclosure of which is incorporated by reference herein in its entirety.

### (a) TECHNICAL FIELD

Exemplary embodiments of the present invention relate to a thin film transistor array panel, and more particularly to a method of manufacturing the same.

### (b) DISCUSSION OF RELATED ART

Displays such as a liquid crystal display (LCD) and an organic light emitting diode (OLED) display may include multiple pairs of electric field generating electrodes and an electro-optical active layer disposed between the pairs of electric field generating electrodes. The LCD may include a liquid crystal layer as the electro-optical active layer, and the OLED may include an organic light emitting layer as the electro-optical active layer.

One of a pair of field generating electrodes is generally connected to a switching element to receive an electrical signal, and the electro-optical active layer may convert the electrical signal into an optical signal, thus displaying an image.

A thin film transistor (TFT), which may be a three-terminal element, may be the switching element in a display device. Signal lines of a gate line transferring a scanning signal for controlling the thin film transistor and a data line transferring a signal applied to a pixel electrode may be included in a display device.

### SUMMARY

Exemplary embodiments of the present invention may provide a thin film transistor array panel which reduces or prevents a reduction in semiconductor performance.

A thin film transistor array panel according to an exemplary embodiment of the present invention includes a substrate and a gate electrode disposed on the substrate. A gate insulating layer is disposed on the substrate and covers the gate electrode. A semiconductor layer is disposed on the gate insulating layer and includes a channel region, a source region, and a drain region. The source and drain regions are separated from each other by the channel region. An etch stopper is disposed on the semiconductor layer. A passivation layer is disposed on the semiconductor layer and covers the etch stopper. A source electrode and a drain electrode are disposed on the passivation layer and are respectively connected to the source region and the drain region. The passivation layer includes aluminum oxide (AlOₓ).

The passivation layer may include a first sub-passivation layer in contact with an upper surface of the semiconductor layer.

The passivation layer may further include a second sub-passivation layer which is separated from the semiconductor layer by the first sub-passivation layer.

The second sub-passivation layer may be in contact with an upper surface of the first sub-passivation layer.

The second sub-passivation layer may include one selected from a silicon nitride (SiNₓ) and silicon oxide (SiOₓ).

The etch stopper need not overlap the source region and the drain region of the semiconductor layer.

The etch stopper may include at least one among silicon oxynitride (SiOₓN_{y}), silicon nitride (SiNₓ), silicon oxide (SiOₓ), and titanium oxide (TiOₓ).

A thin film transistor array panel according to another exemplary embodiment of the present invention includes a substrate and a semiconductor layer disposed on the substrate. The semiconductor layer includes a channel region, a source region, and a drain region. The source and drain regions are separated by the channel region. A gate insulating layer is disposed on the semiconductor layer. A gate electrode is disposed on the gate insulating layer. A passivation layer is disposed on the substrate and covers the source region and the drain region of the semiconductor layer, and the gate electrode. An interlayer insulating layer is disposed on the passivation layer. A source electrode and a drain electrode are disposed on the interlayer insulating layer and are respectively connected to the source region and the drain region. The passivation layer includes aluminum oxide (AlOₓ).

The passivation layer may include a first sub-passivation layer in contact with an upper surface of the semiconductor layer.

The passivation layer may further include a second sub-passivation layer which is separated from the semiconductor layer by the first sub-passivation layer.

The second sub-passivation layer may be in contact with an upper surface of the first sub-passivation layer.

The second sub-passivation layer may include at least one selected from silicon nitride (SiNₓ) and silicon oxide (SiOₓ).

A manufacturing method of a thin film transistor array panel according to an exemplary embodiment of the present invention includes forming a gate electrode on a substrate. A gate insulating layer is formed covering the gate electrode on the substrate. A semiconductor layer is formed on the gate insulating layer. An etch stopper is formed on the semiconductor layer. A source region and a drain region are formed in the semiconductor layer. A passivation layer is formed including aluminum oxide (AlOₓ) on the semiconductor layer to cover the etch stopper. An interlayer insulating layer is formed on the passivation layer.

The passivation layer may include a first sub-passivation layer in contact with an upper surface of the semiconductor layer.

The method may further include forming a second sub-passivation layer including one selected from silicon nitride (SiNₓ) and silicon oxide (SiOₓ) on the first sub-passivation layer.

In the step of forming the source region and the drain region, the channel region may be formed at a portion of the semiconductor layer overlapping the etch stopper, and the source region and the drain region may be separated from each other by the channel region.

The etch stopper may include at least one of silicon oxynitride (SiOₓN_{y}), silicon nitride (SiNₓ), silicon oxide (SiOₓ), and titanium oxide (TiOₓ).

### BRIEF DESCRIPTION OF THE DRAWINGS

FIG. 1 is a cross-sectional view of a thin film transistor array panel according to an exemplary embodiment of the present invention.

FIG. 2 to FIG. 6 are views showing a process of manufacturing the thin film transistor array panel of FIG. 1.

FIG. 7 is a cross-sectional view of a thin film transistor array panel according to another exemplary embodiment of the present invention.

FIG. 8 is a cross-sectional view of a thin film transistor array panel according to another exemplary embodiment of the present invention.

### DETAILED DESCRIPTION OF THE EMBODIMENTS

Exemplary embodiments of the present invention will be described more fully hereinafter with reference to the accompanying drawings, in which exemplary embodiments of the present invention are shown. As those skilled in the art would realize, the described embodiments may be modified in various different ways, all without departing from the spirit or scope of the present invention.

The same reference numerals may refer to the same or similar constituent elements through the specification and drawings.

In the drawings, the thickness of layers, films, panels, or regions may be exaggerated for clarity. In the drawings, the thicknesses of some layers and areas may be exaggerated for clarity.

It will be understood that when an element such as a layer, film, region, or substrate is referred to as being “on” another element, it may be directly on the other element or intervening elements may be present. When an element is referred to as being “directly on” another element, there are no intervening elements present.

The phrase “in a plan view” may refer to when an object portion is viewed from the above. The phrase “in a cross-section” may refer to when a cross-section taken by vertically cutting an object portion is viewed from the side.

A thin film transistor array panel according to an exemplary embodiment of the present invention will be described below in more detail with reference to accompanying drawings.

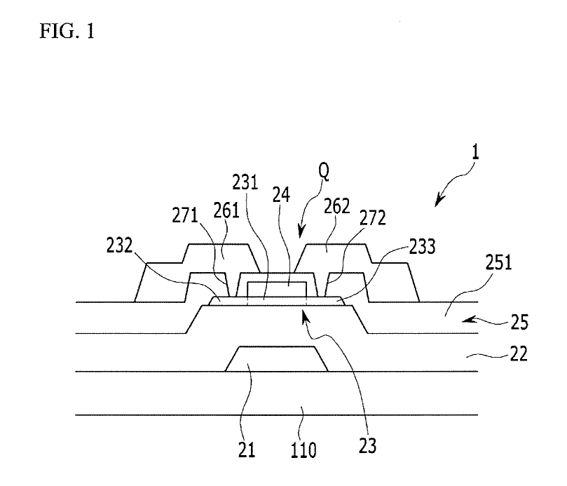

FIG. 1 is a cross-sectional view of a thin film transistor array panel according to an exemplary embodiment of the present invention.

Referring to FIG. 1, a thin film transistor array panel 1 according to an exemplary embodiment of the present invention may include a substrate 110, a gate electrode 21, a gate insulating layer 22, a semiconductor layer 23, an etch stopper 24, a passivation layer 25, a source electrode 261, and a drain electrode 262.

The substrate 110 may include an insulation substrate including glass, quartz, a ceramic material, or a plastic material. However, exemplary embodiments of the present invention are not limited thereto, and the substrate 110 may include a metallic substrate including stainless steel, for example.

The gate electrode 21 may selectively apply a gate voltage for switching a thin film transistor Q. The gate electrode 21 may include a single metal. For example, the gate electrode 21 may include one material among molybdenum (Mo), titanium (Ti), and tungsten (W). The gate electrode 62 may include a deposition structure. The deposition structure may include titanium (Ti), aluminum (Al), and/or titanium (Ti).

A buffer layer may be disposed between the substrate 110 and the gate electrode 21. The buffer layer may reduce or prevent impurities from permeating the substrate 110 and may planarize a surface of the substrate 110. The buffer layer may include one or more of various materials. For example, the buffer layer may include one of silicon nitride (SiNₓ), silicon dioxide (SiOₓ), and silicon oxynitride (SiOₓN_{y}). However, exemplary embodiments of the present invention are not limited thereto. The buffer layer may be omitted according to a type and process conditions of the substrate.

The gate insulating layer 22 may be disposed on the substrate 110 and may cover the gate electrode 21. The gate insulating layer 22 may include a ceramic-based material such as silicon nitride (SiNₓ) or silicon oxide (SiOₓ).

The semiconductor layer 23 may include a polysilicon layer and may be disposed on the gate insulating layer 22.

The semiconductor layer 23 may include amorphous silicon, crystallized silicon, or an oxide semiconductor. When the semiconductor layer 23 includes the oxide semiconductor, the semiconductor layer 23 may include at least one among zinc (Zn), indium (In), tin (Sn), gallium (Ga), and hafnium (Hf).

The semiconductor layer 23 may include a channel region 231 where an impurity is not doped, and a source region 232 and a drain region 233 where an ion material is doped on respective sides of the channel region 231. An ionic material doped in the source region 232 and the drain region 233 may include p-type impurities, such as boron (B). For example, the ionic material may be B₂H₆. The impurity may be changed depending on a type of the thin film transistor. For example, the semiconductor layer 23 may be doped with one material among B, P, As, and Ni.

The etch stopper 24 may be disposed on an upper surface of the channel region 231 of the semiconductor layer 23. The etch stopper 24 may overlap the channel region 231 of the semiconductor layer 23, and might not overlap the source region 232 and the drain region 233 of the semiconductor layer 23.

The etch stopper 24 of the thin film transistor array panel 1 according to an exemplary embodiment of the present invention may include a layer including one of silicon oxynitride (SiOₓN_{y}), silicon nitride (SiNₓ), silicon oxide (SiOₓ), and titanium oxide (TiOₓ).

The passivation layer 25 may cover the source region 232, the drain region 233, and the etch stopper 24 of the semiconductor layer 23. The passivation layer 25 may protect the semiconductor layer 23 and may maintain the semiconductor characteristics (e.g., a level of performance) of the semiconductor layer 23.

The passivation layer 25 of the thin film transistor array panel 1 according to an exemplary embodiment of the present invention may include a first sub-passivation layer 251.

When the first sub-passivation layer 251 is in contact with the semiconductor layer 23 including silicon nitride (SiNₓ), a relatively large number of protons may be included in the semiconductor layer 23 including silicon nitride (SiNₓ). Thus, the protons may diffuse into the semiconductor layer 23 and may reduce the semiconductor characteristics of the semiconductor layer 23.

The first sub-passivation layer 251 of the thin film transistor array panel 1 according to an exemplary embodiment of the present invention may be in contact with the upper surface of the semiconductor layer 23. The first sub-passivation layer 251 may be in contact with the upper surfaces of the source region 232 and the drain region 233. The first sub-passivation layer 251 may be an aluminum oxide (AlOₓ) layer, which may include aluminum oxide (AlOₓ).

When the first sub-passivation layer 251 contacting the upper surface of the semiconductor layer 23 includes aluminum oxide (AlOₓ), diffusion of protons to the semiconductor layer 23 from another layer such as an interlayer insulating layer disposed on the passivation layer 25 may be reduced or prevented.

When the first sub-passivation layer 251 includes aluminum oxide (AlOₓ), the content of hydrogen (e.g., Hi⁺ ions) in the passivation layer 25 may be relatively low and a reduction of the semiconductor characteristics of the semiconductor layer 23 by the diffusion of protons may be reduced or eliminated. For example, the hydrogen content of the passivation layer 25 when the first sub-passivation layer 251 includes aluminum oxide (AlOₓ) may be relatively lower than when the first sub-passivation layer 251 includes silicon nitride (SiNₓ).

According to an exemplary embodiment of the present invention, the passivation layer 25 may include the first sub-passivation layer 251, but two or more sub-passivation layers may be formed. When forming two or more sub-passivation layers, the sub-passivation layer contacting the semiconductor layer 23 may include aluminum oxide (AlOₓ).

The source electrode 261 and the drain electrode 262 may be disposed on the upper surface of the passivation layer 25 and may be respectively connected to the source region 232 and the drain region 233 of the semiconductor layer 23 through contact holes 271 and 272 penetrating the passivation layer 25.

The interlayer insulating layer covering the source electrode 261 and the drain electrode 262 may be disposed on the passivation layer 25.

A manufacturing method of a thin film transistor array panel according to an exemplary embodiment of the present invention will be described in more detail below.

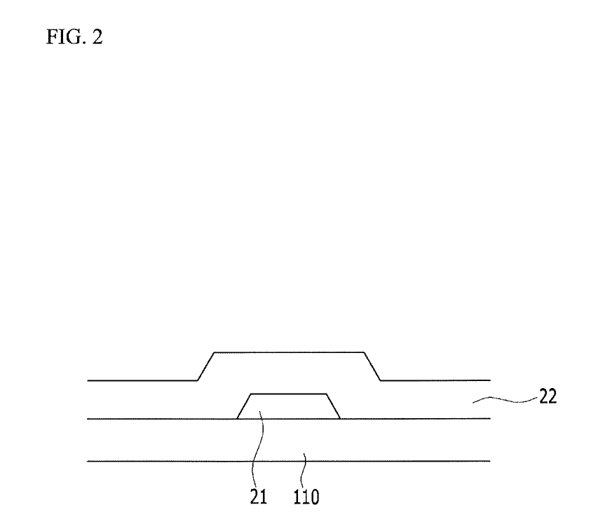

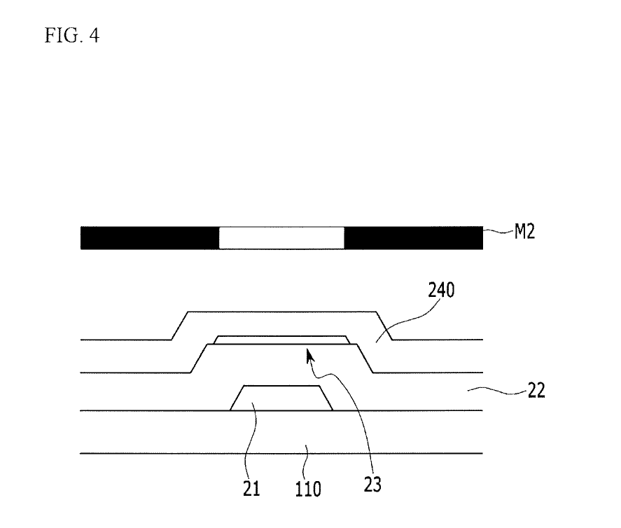

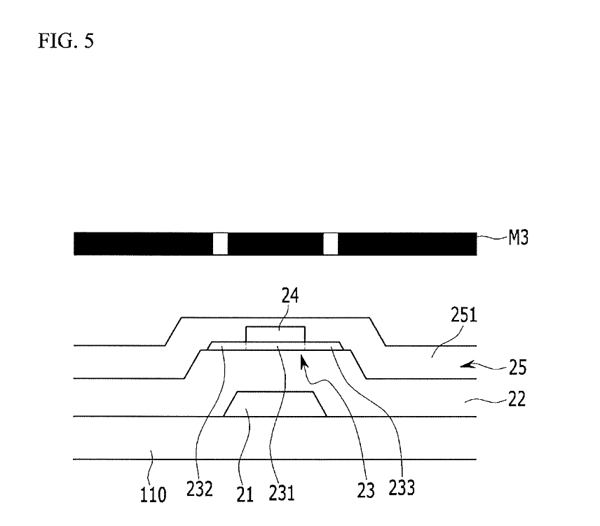

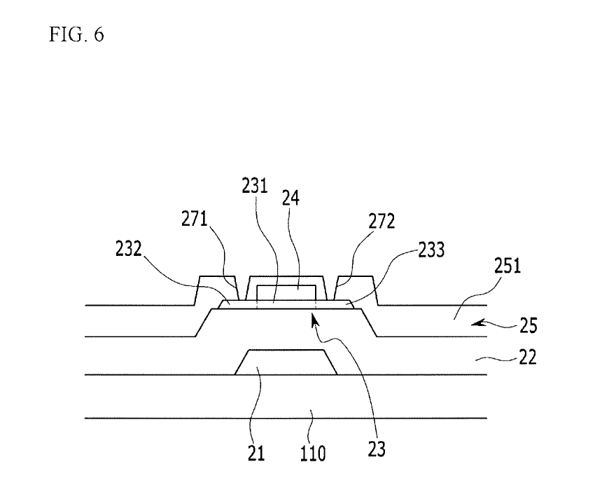

FIG. 2 to FIG. 6 are views showing a process of manufacturing the thin film transistor array panel of FIG. 1.

Referring to FIG. 2, the gate electrode 21 may be formed on the substrate 110. The gate insulating layer 22 may cover the gate electrode 21 and may be formed on the substrate 110 and the gate electrode 21.

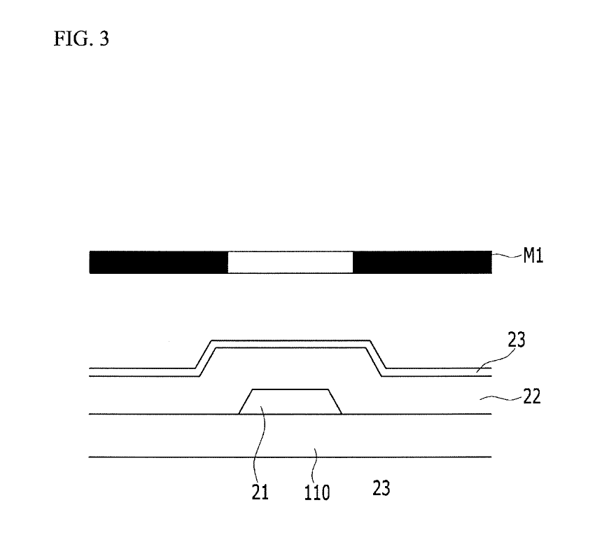

Referring to FIG. 3 to FIG. 6, the semiconductor layer 23 may be formed on the gate insulating layer 22 and may be patterned by using a first mask M1. Thus, the semiconductor layer 23 may be formed into a pattern overlapping the gate electrode 21.

An etch stopper layer 240 covering the gate insulating layer 22 and the semiconductor layer 23 may be formed and patterned by using a second mask M2 to form the etch stopper 24 covering the part of the semiconductor layer 23.

The part of the semiconductor layer 23 overlapping the etch stopper 24 may become the channel region 231.

The source region 232 and the drain region 233 may be formed in the semiconductor layer 23.

The channel region 231 of the semiconductor layer 23 may overlap the etch stopper 24 and the impurity may be doped in the region that does not overlap the etch stopper 24 outside the channel region 231, thus forming the source region 232 and the drain region 233. A p-type impurity or an n-type impurity may be doped in the source region 232 and the drain region 233.

The first sub-passivation layer 251 covering the semiconductor layer 23 and the etch stopper 24 and including aluminum oxide (AlOₓ) may be formed. The first sub-passivation layer 251 may be in contact with the upper surface of the source region 232 and the drain region 233 of the semiconductor layer 23.

A third mask M3 may be used to form the passivation layer 25 including the first sub-passivation layer 251. The passivation layer 25 may be patterned to form the first contact hole 271 and the second contact hole 272. The first contact hole 271 and the second contact hole 272 may respectively penetrate the passivation layer 25 for connection with the source region 232 and the drain region 233.

The source electrode 261 and the drain electrode 262 connected to the source region 232 and the drain region 233 through the first contact hole 271 and the second contact hole 272 may be formed on the passivation layer 25.

According to an exemplary embodiment of the present invention, when the first sub-passivation layer 251 contacting the upper surface of the semiconductor layer 23 includes aluminum oxide (AlOₓ), a diffusion of protons into the semiconductor layer 23 from other layers such as the interlayer insulating layer disposed on the passivation layer 25 may be reduced or prevented.

When the first sub-passivation layer 251 includes aluminum oxide (AlOₓ), the content of hydrogen (e.g., H⁺ ions) in the passivation layer 25 may be relatively low and a reduction of the semiconductor characteristics of the semiconductor layer 23 by the diffusion of protons may be reduced or eliminated. For example, the hydrogen content of the passivation layer 25 when the first sub-passivation layer 251 includes aluminum oxide (AlOₓ) may be relatively lower than when the first sub-passivation layer 251 includes silicon nitride (SiNₓ).

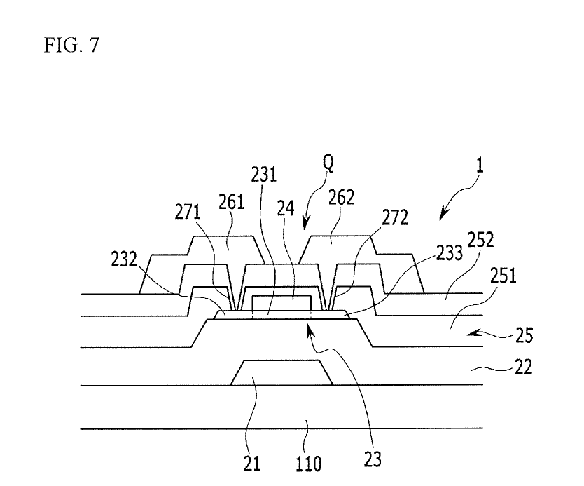

FIG. 7 is a cross-sectional view of a thin film transistor array panel according to another exemplary embodiment of the present invention.

The thin film transistor array panel described with reference to FIG. 7 may be substantially the same as the thin film transistor array panel described with reference to FIG. 1 to FIG. 6 except for the configuration of the passivation layer, and duplicative descriptions may be omitted.

Referring to FIG. 7, the passivation layer 25 of the thin film transistor array panel 1 according to an exemplary embodiment of the present invention may include the first sub-passivation layer 251 and a second sub-passivation layer 252.

The first sub-passivation layer 251 may include aluminum oxide (AlOₓ), and may cover the upper surface of the semiconductor layer 23 and the etch stopper 24.

The second sub-passivation layer 252 may be formed on the upper surface of the first sub-passivation layer 251. The second sub-passivation layer 252 may include silicon nitride (SiNₓ) or silicon oxide (SiOₓ).

The second sub-passivation layer 252 including silicon nitride (SiNₓ) or silicon oxide (SiOₓ) may be separated from the semiconductor layer 23 and the etch stopper 24 via the first sub-passivation layer 251 including aluminum oxide (AlOₓ).

Thus, a diffusion of protons included in the second sub-passivation layer 252 into the semiconductor layer 23 may be reduced or prevented.

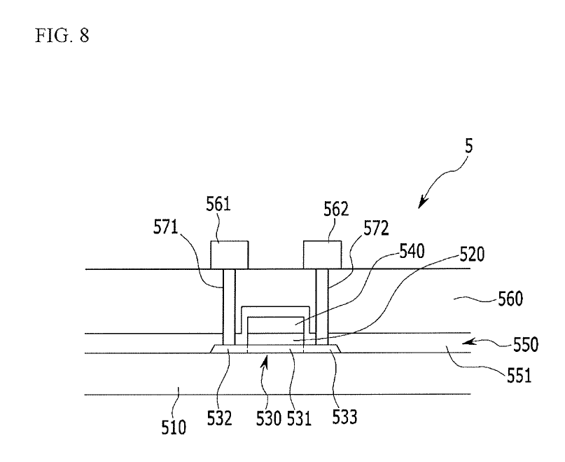

FIG. 8 is a cross-sectional view of a thin film transistor array panel according to another exemplary embodiment of the present invention.

The thin film transistor array panel described with reference to FIG. 8 may be substantially the same as the thin film transistor array panel described with reference to FIG. 1 to FIG. 6 except for the position of the gate electrode, and duplicative descriptions may be omitted.

Referring to FIG. 8, a thin film transistor array panel 5 according to an exemplary embodiment of the present invention may include a substrate 510, a semiconductor layer 530, a gate insulating layer 520, a gate electrode 540, a passivation layer 550, an interlayer insulating layer 560, a source electrode 561, and a drain electrode 562.

The semiconductor layer 530 may be formed on an upper surface of the substrate 510 and may include a channel region 531, a source region 532, and a drain region 533.

The gate insulating layer 520 may be formed on the semiconductor layer 530 and may overlap the channel region 531.

The gate electrode 540 may be disposed on the gate insulating layer 520. The passivation layer 550 may be formed on the substrate 510 and may cover the source region 532, the drain region 533, and the gate electrode 540 of the semiconductor layer 530.

The interlayer insulating layer 560 may be formed on the passivation layer 550. The source electrode 561 and the drain electrode 562 may be disposed on the interlayer insulating layer 560. The source electrode 561 and the drain electrode 562 may be respectively connected to the source region 532 and the drain region 533 through a first contact hole 571 and a second contact hole 572 penetrating the passivation layer 550 and the interlayer insulating layer 560.

The passivation layer 550 may include a first sub-passivation layer 551 contacting an upper surface of the source region 532 and the drain region 533. The first sub-passivation layer 551 may include aluminum oxide (AlOₓ).

Thus, a diffusion of protons from the interlayer insulating layer 560 formed on the passivation layer 550 into the semiconductor layer 530 may be reduced or prevented, and a deterioration of the semiconductor characteristics of the semiconductor layer 530 may be reduced or prevented.

While the present invention has been shown and described with reference to the exemplary embodiments thereof, it will be apparent to those of ordinary skill in the art that various changes in form and detail may be made thereto without departing from the spirit and scope of the present invention.

What is claimed is:

1. A thin film transistor array panel comprising:
a substrate;
a gate electrode disposed on the substrate;
a gate insulating layer disposed on the substrate and covering the gate electrode;
a semiconductor layer disposed on the gate insulating layer and including a channel region, a source region, and drain region, the source and drain regions being separated from each other by the channel region;
an etch stopper disposed on the semiconductor layer;
a passivation layer disposed on the semiconductor layer and covering the etch stopper; and
a source electrode and a drain electrode which are disposed on the passivation layer and respectively connected to the source region and the drain region,
wherein the passivation layer includes aluminum oxide (AlOₓ).

2. The thin film transistor array panel of claim 1, wherein the passivation layer comprises a first sub-passivation layer in contact with an upper surface of the semiconductor layer.

3. The thin film transistor array panel of claim 2, wherein the passivation layer further includes a second sub-passivation layer which is separated from the semiconductor layer by the first sub-passivation layer.

4. The thin film transistor array panel of claim 3, wherein the second sub-passivation layer is in contact with an upper surface of the first sub-passivation layer.

5. The thin film transistor array panel of claim 4, wherein the second sub-passivation layer includes one selected from silicon nitride (SiNₓ) and silicon oxide (SiOₓ).

6. The thin film transistor array panel of claim 1, wherein the etch stopper does not overlap the source region and the drain region of the semiconductor layer.

7. The thin film transistor array panel of claim 6, wherein the etch stopper includes at least one among silicon oxynitride (SiOₓN_{y}), silicon nitride (SiNₓ), silicon oxide (SiOₓ), and titanium oxide (TiOₓ).

8. A thin film transistor array panel comprising:
a substrate;
a semiconductor layer disposed on the substrate and including a channel region, a source region, and a drain region, the source and drain regions being separated by the channel region;
a gate insulating layer disposed on the semiconductor layer;
a gate electrode disposed on the gate insulating layer;
a passivation layer disposed on the substrate and covering the source region and the drain region of the semiconductor layer, and the gate electrode;
an interlayer insulating layer disposed on the passivation layer; and
a source electrode and a drain electrode which are disposed on the interlayer insulating layer and respectively connected to the source region and the drain region,
wherein the passivation layer includes aluminum oxide (AlOₓ).

9. The thin film transistor array panel of claim 8, wherein the passivation layer comprises a first sub-passivation layer in contact with an upper surface of the semiconductor layer.

10. The thin film transistor array panel of claim 9, wherein the passivation layer further includes a second sub-passivation layer which is separated from the semiconductor layer by the first sub-passivation layer.

11. The thin film transistor array panel of claim 10, wherein the second sub-passivation layer is in contact with an upper surface of the first sub-passivation layer.

12. The thin film transistor array panel of claim 11, wherein the second sub-passivation layer includes at least one selected from silicon nitride (SiNₓ) and silicon oxide (SiOₓ).

13. A method for manufacturing a thin film transistor array panel comprising:
forming a gate electrode on a substrate;
forming a gate insulating layer covering the gate electrode on the substrate;
forming a semiconductor layer on the gate insulating layer;
forming an etch stopper on the semiconductor layer;
forming a source region and a drain region in the semiconductor layer;
forming a passivation layer including aluminum oxide (AlOₓ) on the semiconductor layer to cover the etch stopper; and
forming an interlayer insulating layer on the passivation layer.

14. The method of claim 13, wherein the passivation layer comprises a first sub-passivation layer in contact with an upper surface of the semiconductor layer.

15. The method of claim 14, further comprising forming a second sub-passivation layer including one selected from silicon nitride (SiNₓ) and silicon oxide (SiOₓ) on the first sub-passivation layer.

16. The method of claim 13, wherein in the step of forming the source region and the drain region, the channel region is formed at a portion of the semiconductor layer overlapping the etch stopper, and the source region and the drain region are separated from each other by the channel region.

17. The method of claim 13, wherein the etch stopper includes at least one of silicon oxynitride (SiOₓN_{y}), silicon nitride (SiNₓ), silicon oxide (SiOₓ), and titanium oxide (TiOₓ).
